(19) United States
(12) Patent Application Publication
(10) Pub. No.: US 2016/0321138 A1
(43) Pub. Date: Nov. 3, 2016

(54) INFORMATION REPLAY DEVICE, INFORMATION REPLAY METHOD, INFORMATION STORAGE DEVICE, AND INFORMATION STORAGE METHOD

(71) Applicant: HITACHI, LTD., Tokyo (JP)

(72) Inventors: Yusuke NAKAMURA, Tokyo (JP); Keisuke YAMAMOTO, Tokyo (JP)

(73) Assignee: HITACHI, LTD., Tokyo (JP)

(21) Appl. No.: 15/109,315

(22) PCT Filed: Jan. 20, 2014
(86) PCT No.: PCT/JP2014/050883

§ 371 Date: Jun. 30, 2016

(51) Int. Cl. G06F 11/10; H03M 13/27; G11B 7/0065

(52) U.S. Cl. CPC G06F 11/1076; G11B 7/0065; H03M 13/2792; G11B 2007/240025

(57) ABSTRACT

A modulation method has a high encoding rate for generating a pattern having a lower limit for the number of successive pixels in a spatial light modulator. An information recording device includes: an encoding unit that performs error correction encoding of input data; an interleaving unit that switches the output sequence of the error correction encoding unit; and an modulation unit that performs RLL modulation of the output of the interleaving unit on the basis of an RLL modulation trellis. A corresponding information reproducing device includes: a demodulation unit that uses a posteriori probability decoding based on the RLL modulation trellis, to perform RLL demodulation for reproducing recorded information; a deinterleaving unit that reverses the sequence switching; and a decoding unit that performs error correction code decoding using a posteriori probability decoding on the basis of the error correction encoding on the output of the deinterleaving unit.

### TECHNICAL FIELD

The present invention relates to information reproducing devices, information reproducing methods, information recording device, and information recording methods that reproducing information from information recording media.

### BACKGROUND ART

A hologram recording technique is, for example, found in JP 2010-003358 A (Patent Literature 1). A recording pattern of this technique resides in “restrictions are imposed so that the lower limit of the number of continuous ON/OFF pixels in an arrangement with respect to one direction is K K: a natural number). For example, in a case of K=2, the lower limit of the number of continuous pixels becomes 2 pixels; therefore, the numbers of the continuous ON/OFF pixels in the arrangement are 2 pixels, 3 pixels, 4 pixels, and so on, where 2 pixels are continued at minimum, and those of 1 pixel are excluded.” as described in Paragraph 0050 of this publication; and, as described in Paragraph 0051, the technique that “enables densification of K-times in an entire disk as a result” is disclosed.

### CITATION LIST

### Patent Literature

Patent Literature 1: JP-A-2010-003358

### SUMMARY OF INVENTION

### Technical Problem

However, if the high-density recording method of Patent Literature 1 is to be carried out, a specific method of generating a pattern having the lower limit K of the number of continuous pixels in a spatial light modulator is not described, and realization of a modulating method with a high code rate has been a problem.

### Solution to Problem

The above described problem is solved by the invention described, for example, in claims.

### Advantages Effects of Invention

According to the present invention, information recording/reproducing devices that use a modulating method with a high code rate and, at the same time, have a high error correction capability by improving the consistency of an EXIT curve of a decoding method and a demodulating method.

### BRIEF DESCRIPTION OF DRAWINGS

FIG. 1 is a schematic diagram showing Example of an optical-information recording/reproducing device.

FIG. 2 is a schematic diagram showing Example of a pickup in the optical-information recording/reproducing device.

FIG. 3 is a schematic diagram showing Example of the pickup in the optical-information recording/reproducing device.

FIG. 4 is a schematic diagram showing Example of the pickup in the optical-information recording/reproducing device.

FIG. 5 are schematic diagrams showing Example of an operation flow of the optical-information recording/reproducing device.

FIG. 6 is a schematic diagram showing Example of a signal generating circuit in the optical-information recording/reproducing device.

FIG. 7 is a schematic diagram showing Example of an operation flow of the signal generating circuit.

FIG. 8 is a schematic diagram showing Example of the signal processing circuit in the optical-information recording/reproducing device.

FIG. 9 is a schematic diagram showing Example of an operation flow of the signal processing circuit.

FIG. 10 is a schematic diagram showing Example of an RLL demodulating circuit.

FIG. 11 is a schematic diagram showing Example of the RLL demodulating circuit.

FIG. 12 is a schematic diagram showing Example of a convolutional-code decoding circuit.

FIG. 13 is a schematic diagram showing Example of the convolutional-code decoding circuit.

FIG. 14 is a diagram showing state transitions of 1 bit of RLL (1, ∞).

FIG. 15 is a diagram showing state transitions of 2 bits of RLL (1, ∞).

FIG. 16 is a diagram showing state transitions of 3 bits of RLL (1, ∞).

FIG. 17 is a diagram showing state transitions of 3 bits of RLL (1, ∞).

FIG. 18 is a diagram showing state transitions of 3 bits of RLL (1, ∞).

FIG. 19 is a table showing state transitions of 3 bits of RLL (1, ∞).

FIG. 20 is a table showing the state transitions of 3 bits of RLL (1, ∞) in consideration of Prebit.

FIG. 21 is a table showing the state transitions of 3 bits of RLL (1, ∞) after dissolving NRZI.

FIG. 22 is a trellis line diagram of RLL (1, ∞) after dissolving NRZI.

FIG. 23 is a diagram showing an EXIT chart of an RLL demodulating circuit.

FIG. 24 is a trellis line diagram of RLL (1, ∞) after dissolving NRZI.

FIG. 25 is a diagram showing an EXIT chart of the RLL demodulating circuit.

FIG. 26 is a schematic diagram showing Example of a convolutional-code encoding circuit.

FIG. 27 is a schematic diagram showing Example of a convolutional encoder.

FIG. 28 is a schematic diagram showing Example of the convolutional encoder.

FIG. 29 is a schematic diagram showing Example of the convolutional-code decoding circuit.

FIG. 30 is a diagram showing an EXIT chart of the RLL demodulating circuit and the convolutional-code decoding circuit.

FIG. 31 is a diagram showing an EXIT chart of the RLL demodulating circuit and the convolutional-code decoding circuit.

FIG. 32 is a diagram showing an EXIT chart of the RLL demodulating circuit and the convolutional-code decoding circuit.

FIG. 33 is a diagram showing reproducing performance of the signal processing circuit.

FIG. 34 is a diagram showing a terminal processing method according to tail biting in the convolutional code circuit.

FIG. 35 is a diagram showing a terminal processing method according to zero-tail in the convolutional code circuit.

FIG. 36 is a schematic diagram showing Example of the convolutional encoding circuit.

FIG. 37 is a schematic diagram showing Example of a signal processing circuit in an optical-information recording/reproducing device.

FIG. 38 is a schematic diagram showing Example of a soft-symbol encoding circuit.

FIG. 39 is a schematic diagram showing Example of a turbo equalizing circuit.

FIG. 40 is a schematic diagram showing Example of an operation flow of the signal processing circuit.

FIG. 41 is a table showing state transitions of 3 bits of RLL (1, ∞).

FIG. 42 is a trellis line diagram of RLL (1, ∞).

### DESCRIPTION OF EMBODIMENTS

Hereinafter, Examples of the present invention will be described by using drawings.

### EXAMPLE 1

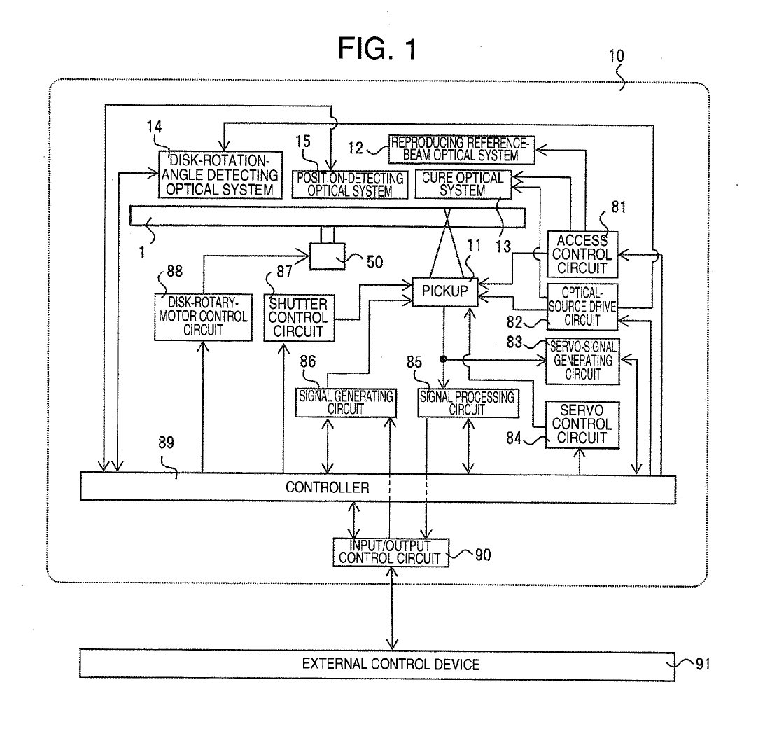

An embodiment of the present invention will be described in accordance with drawings. FIG. 1 is a block diagram showing a recording/reproducing device of an optical-information recording medium which records and/or reproduces digital information by utilizing holography.

An optical-information recording/reproducing device 10 is connected to an external control device 91 via an input/output control circuit 90. In a case of recording, the optical-information recording/reproducing device 10 receives information signals, which are to be recorded, from the external control device 91 by the input/output control circuit 90. In a case of reproducing, the optical-information recording/reproducing device 10 transmits reproduced information signals to the external control device 91 by the input/output control circuit 90.

The optical-information recording/reproducing device 10 is provided with a pickup 11, a reproducing reference-beam optical system 12, a Cure optical system 13, a disk-rotation-angle detecting optical system 14, a position-detecting optical system 15, and a rotary motor 50; and the optical-information recording medium 1 is configured to be rotatable by the rotary motor 50.

The pickup 11 functions to output a reference beam and a signal beam to the optical-information recording medium 1 and record digital information onto the recording medium by utilizing holography. In this process, the information signals, which are to be recorded, are transmitted to a spatial light modulator in the pickup 11 via a signal generating circuit 86 by a controller 89, and the signal beam is modulated by the spatial light modulator.

When the information recorded in the optical-information recording medium 1 is to be reproduced, light waves which cause the reference beam, which is output from the pickup 11, to be input to the optical-information recording medium in the opposite direction of that of recording is generated by the reproducing reference-beam optical system 12. A reproducing beam reproduced by the reproducing reference beam is detected by a later-described optical detector, which is in the pickup 11, and signals thereof are reproduced by a signal processing circuit 85.

The irradiation time of the reference beam and the signal beam radiated to the optical-information recording medium 1 can be adjusted by controlling the opened/closed time of a shutter in the pickup 11 by the controller 89 via a shutter control circuit 87.

The Cure optical system 13 functions to generate optical beams which are used in pre-cure and post-cure of the optical-information recording medium 1. The pre-cure is a preceding process of radiating a predetermined optical beam in advance before a reference beam and a signal beam are radiated to a desired position when information is to be recorded at the desired position in the optical-information recording medium 1. The post-cure is a post-process of, after information is recorded at a desired position in the optical-information recording medium 1, radiating a predetermined optical beam in order to disable additional recording at the desired position.

The disk-rotation-angle detecting optical system 14 is used for detecting the rotation angle of the optical-information recording medium 1. If the optical-information recording medium 1 is to be adjusted to a predetermined rotation angle, a signal corresponding to the rotation angle is detected by the disk-rotation-angle detecting optical system 14, and the rotation angle of the optical-information recording medium 1 can be controlled by the controller 89 via a disk-rotary-motor control circuit 88 by using the detected signal.

A predetermined optical-source drive current is supplied from an optical-source drive circuit 82 to optical sources in the pickup 11, the Cure optical system 13, and the disk-rotation-angle detecting optical system 14, and optical beams can be emitted from the respective optical sources by predetermined light intensities.

Moreover, the pickup 11 and the disk-Cure optical system 13 are provided with a mechanism which can slide a position in the radial direction of the optical-information recording medium 1, and positional control is carried out via an access control circuit 81.

Meanwhile, the recording techniques utilizing the principles of angle multiplexing of holography have a tendency that the allowable errors with respect to misalignment of reference-beam angles are extremely small.

Therefore, it is required to provide a mechanism, which detects the misaligned amount of the reference-beam angle, in the pickup 11, generate a signal for servo control by a servo-signal generating circuit 83, and provide a servomechanism, which is for correcting the misaligned amount via a servo control circuit 84, in the optical-information recording/reproducing device 10.

Meanwhile, some of optical-system configurations or all of optical-system configurations of the pickup 11, the Cure optical system 13, the disk-rotation-angle detecting optical system 14, and the position-detecting optical system 15 may be integrated into one and simplified.

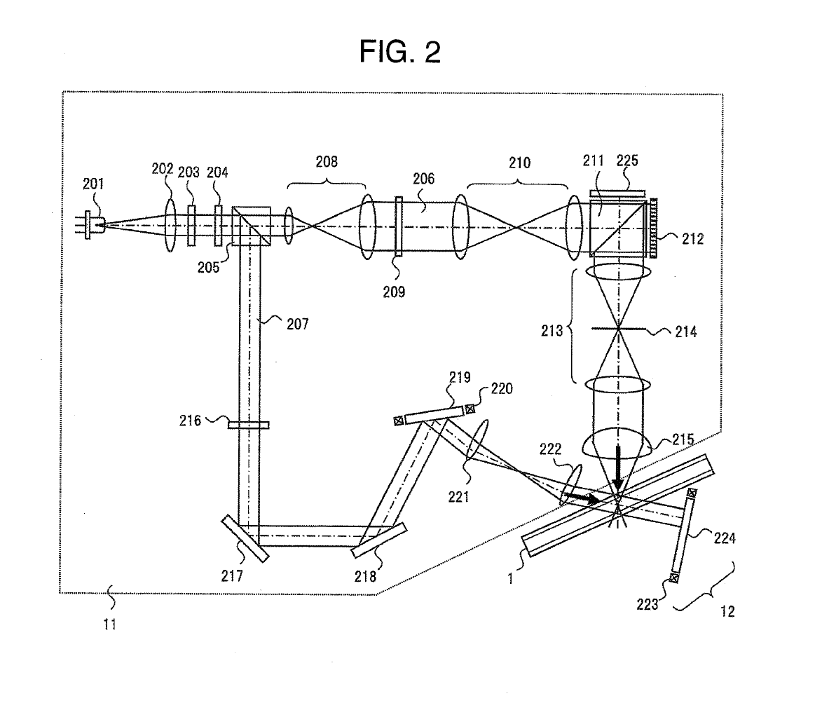

FIG. 2 shows recording principles in an example of a basic optical-system configuration of the pickup 11 in the optical-information recording/reproducing device 10. An optical beam output from an optical source 201 transmits through a collimator lens 202 and is input to a shutter 203. When the shutter 203 is open, the optical beam passes through the shutter 203, is then subjected to control of polarization directions, for example, so that the light intensity ratio of p-polarization and s-polarization is caused to be a desired ratio by an optical element 204 composed of, for example, a half-wavelength plate, and is then input to a polarization beam splitter (PBS) prism 205.

The optical beam, which has transmitted through the PBS prism 205, works as a signal beam 206, is subjected to expansion of an optical beam diameter by a beam expander 208, then transmits through a phase mask 209, relay lenses 210, and a PBS prism 211, and is input to a spatial light modulator 212.

The signal beam to which information is added by the spatial light modulator 212 is reflected by the PBS prism 211 and propagates through relay lenses 213 and a spatial filter 214. Then, the signal beam is condensed onto the optical-information recording medium 1 by an objective lens 215.

Meanwhile, the optical beam reflected by the PBS prism 205 works as a reference beam 207, is set to a predetermined polarization direction by a polarization-direction converting element 216 depending on a recording case or a reproducing case, and is then input to a galvano mirror 219 via a mirror 217 and a mirror 218. Since the angle of the galvano mirror 219 can be adjusted by an actuator 220, the angle of incidence of the reference beam which is input to the optical-information recording medium 1 can be set to a desired angle after passing through a lens 221 and a lens 222. Note that, in order to set the angle of incidence of the reference beam, an element which converts the wave front of the reference beam may be used instead of the galvano mirror.

When the signal beam and the reference beam are input to the optical-information recording medium 1 so as to be overlapped with each other in this manner, an interference pattern is formed in the recording medium, and information is recorded by writing this pattern to the recording medium. Also, since the angle of incidence of the reference beam which is input to the optical-information recording medium 1 can be changed by the galvano mirror 219, recording by angle multiplexing can be carried out.

Hereinafter, regarding the holograms recorded in the same region with different reference-beam angles, the hologram corresponding to each reference-beam angle will be referred to a page, and an aggregate of the pages which have undergone angle multiplexing in the same region will be referred to as a book.

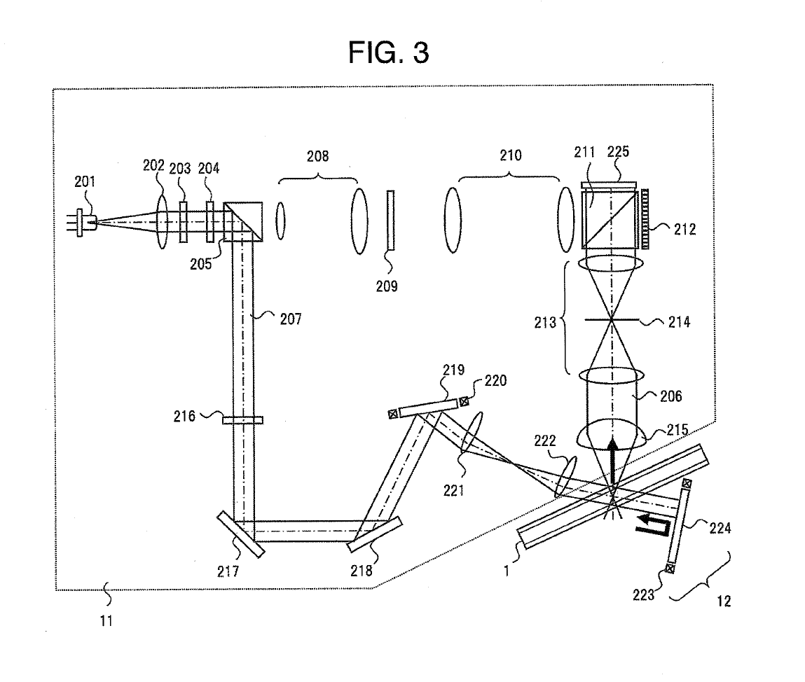

FIG. 3 shows reproducing principles in an example of the basic optical-system configuration of the pickup 11 in the optical-information recording/reproducing device 10. When recorded information is to be reproduced, a reference beam is input to the optical-information recording medium 1 in the above described manner, and the optical beam transmitted through the optical-information recording medium 1 is reflected by a galvano mirror 224, which can be subjected to angle adjustment by an actuator 223, thereby generating a reproducing reference beam thereof.

A reproducing beam reproduced by the reproducing reference beam propagates to the objective lens 215, the relay lenses 213, and the spatial filter 214. Then, the reproducing beam transmits through the PBS prism 211 and is input to an optical detector 225, and the recorded signals can be reproduced. As the optical detector 225, for example, an image pickup element such as a CMOS image sensor or a CCD image sensor can be used, but the optical detector may be any element as long as page data can be reproduced.

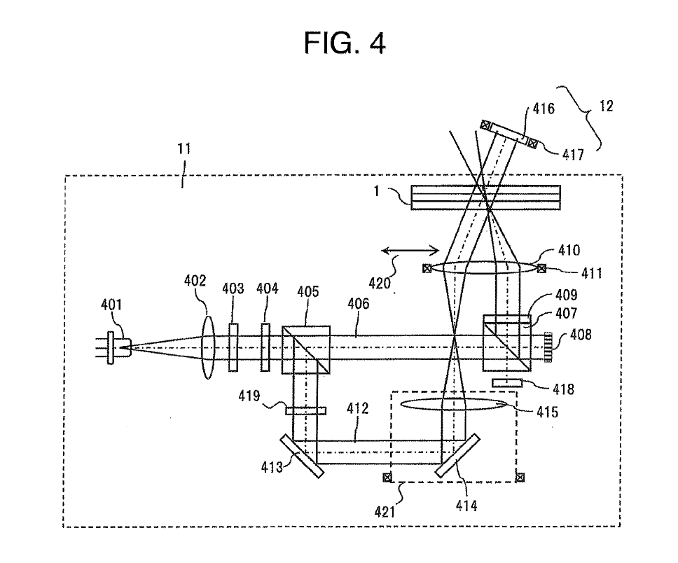

FIG. 4 is a drawing showing another configuration of the pickup 11. In FIG. 4, an optical beam output from an optical source 401 transmits through a collimator lens 402 and is input to a shutter 403. When the shutter 403 is open, the optical beam passes through the shutter 403, is then subjected to control of polarization directions so that the light intensity ratio of p-polarization and s-polarization is caused to be a desired ratio by an optical element 404 composed of, for example, a half-wavelength plate, and is then input to a polarization beam splitter 405.

The optical beam, which has transmitted through the polarization beam splitter 405, is input to a spatial light modulator 408 via a polarization beam splitter 407. A signal beam 406 to which information is added by the spatial light modulator 408 is reflected by the polarization beam splitter 407 and propagates through an angle filter 409, which allows passage of only the optical beams having a predetermined angle of incidence. Then, the signal light beam is condensed onto the hologram recording medium 1 by an objective lens 410.

Meanwhile, the optical beam reflected by the polarization beam splitter 405 works as a reference beam 412, is set to a predetermined polarization direction by a polarization-direction converting element 419 depending on a recording case or a reproducing case, and is then input to a lens 415 via a mirror 413 and a mirror 414. The lens 415 functions to condense the reference beam 412 onto a back-focus surface of the objective lens 410, and the reference beam once condensed onto the back-focus surface of the objective lens 410 is caused to be parallel light again by the objective lens 410 and is input to the hologram recording medium 1.

Herein, the objective lens 410 or an optical block 421 can be driven, for example, in the direction shown by a reference sign 420. When the position of the objective lens 410 or the optical block 421 is shifted along the drive direction 420, the relative position relation of the objective lens 410 and a light condensing point on the back-focus surface of the objective lens 410 is changed. Therefore, the angle of incidence of the reference beam input to the hologram recording medium 1 can be set to a desired angle. Note that instead of driving the objective lens 410 or the optical block 421, the angle of incidence of the reference beam may be set to a desired angle by driving the mirror 414 by an actuator.

When the signal beam and the reference beam are input to the hologram recording medium 1 so as to be overlapped with each other in this manner, an interference pattern is formed in the recording medium, and information is recorded by writing this pattern in the recording medium. Also, when the position of the objective lens 410 or the optical block 421 is shifted along the drive direction 420, the angle of incidence of the reference beam input to the hologram recording medium 1 can be changed; therefore, recording by angle multiplexing can be carried out.

When recorded information is to be reproduced, a reference beam is input to the hologram recording medium 1 in the above described manner, and an optical beam transmitted through the hologram recording medium 1 is reflected by a galvano mirror 416, thereby generating a replying reference beam thereof is generated. A reproducing beam reproduced by the reproducing reference beam propagates through the objective lens 410 and the angle filter 409. Then, the reproducing beam transmits through the polarization beam splitter 407 and is input to an optical detector 418, and the recorded signals can be reproduced.

The optical system shown in FIG. 4 has an advantage that significant downsizing can be carried out by employing the configuration in which the signal beam and the reference beam are input to the same objective lens compared with the optical-system configuration shown in FIG. 2.

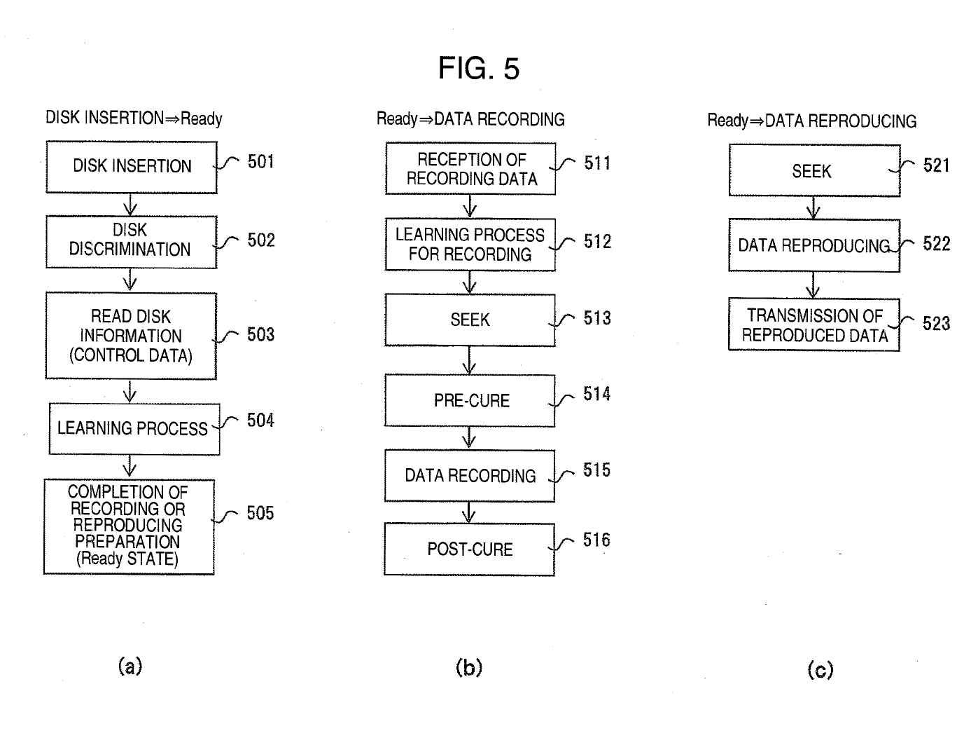

FIG. 5, (a) to (c) shows operation flows of recording and reproducing in the optical-information recording/reproducing device 10. Herein, particularly the flows about recording/reproducing utilizing holography will be described.

FIG. 5, (a) shows the operation flow to completion of preparation of recording or reproducing after the optical-information recording medium 1 is inserted in the optical-information recording/reproducing device 10, FIG. 5, (b) shows the operation flow from a preparation completed state to recording of information into the optical-information recording medium 1, and FIG. 5, (c) shows the operation flow from the preparation completed state to reproducing of the information recorded in the optical-information recording medium 1.

As shown in FIG. 5, (a), when a medium is inserted (501), the optical-information recording/reproducing device 10 carries out disk discrimination, for example, whether the inserted medium is a medium that is to record or reproduce digital information by utilizing holography (502).

As a result of the disk discrimination, if the medium is judged to be an optical-information recording/medium that records or reproduces digital information by utilizing holography, the optical-information recording/reproducing device 10 reads control data, which is provided in the optical-information recording medium, (503) and acquires, for example, information about the optical-information recording medium or, for example, information about various setting conditions in recording or reproducing.

After the control data is read, various adjustments corresponding to the control data and/or a learning process about the pickup 11 (504) is carried out, and the optical-information recording/reproducing device 10 completes the preparation of recording or reproducing (505).

In the operation flow from the preparation completed state to recording of information, as shown in FIG. 5, (b), first, the data to be recorded is received (511), and information corresponding to the data is transmitted to the spatial light modulator in the pickup 11.

Then, depending on needs, various learning processes for recording such as power optimization of an optical source 301 and optimization of the exposure time by a shutter 303 are carried out in advance so that high-quality information can be recorded in the optical-information recording medium (512).

Then, in a seek operation (513), the access control circuit 81 is controlled to locate the positions of the pickup 11 and the Cure optical system 13 at predetermined positions of the optical-information recording medium. If the optical-information recording medium 1 has address information, the address information is reproduced, whether they are located at target positions or not is checked; and, if they are not disposed to the target positions, an operation of calculating the amounts of misalignment from the predetermined positions and locating them again is repeated.

Then, a predetermined region is pre-cured by using an optical beam output from the Cure optical system 13 (514), and the data is recorded by using a reference beam and a signal beam output from the pickup 11 (515).

After the data is recorded, a post-cure is carried out by using an optical beam output from the Cure optical system 13 (516). Depending on needs, the data may be verified.

In the operation flow from the preparation completed state to reproducing of recorded information, as shown in FIG. 5, (c), first, in a seek operation (521), the access control circuit 81 is controlled to locate the positions of the pickup 11 and the reproducing reference-beam optical system 12 to predetermined positions of the optical-information recording medium. If the optical-information recording medium 1 has address information, the address information is reproduced, and whether they are located at the target positions is checked; and, if they are not disposed at the target positions, an operation of calculating the amounts of misalignment from the predetermined positions and locating them again is repeated.

Then, a reference beam is output from the pickup 11, the information recorded in the optical-information recording medium is read (522), and reproduced data is transmitted (523).

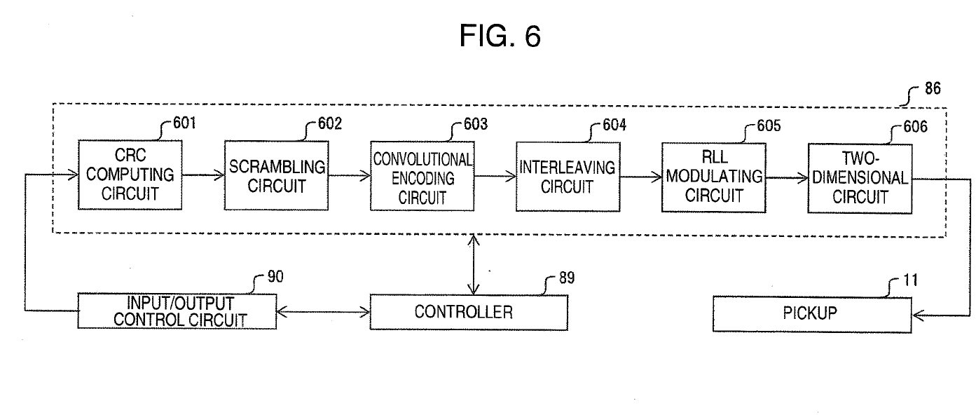

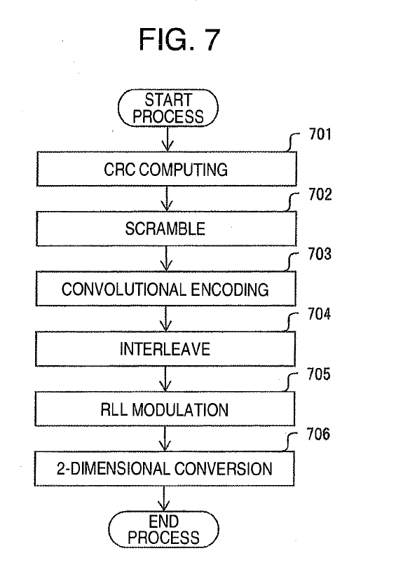

FIG. 6 is a block diagram of the signal generating circuit 86 of the optical-information recording/reproducing device 10, and FIG. 7 is a signal generating flow of the signal generating circuit 86.

In a case of recording, when input of user data to the input/output control circuit 90 is started, the input/output control circuit 90 notifies the controller 89 of the fact that input of the user data has been started. In response to the notification, the controller 89 orders the signal generating circuit 86 to subject the data corresponding to one page input from the input/output control circuit 90 to a recording process. With respect to the data input from the input/output control circuit 90, control of subjecting the user data to CRC conversion is carried out in a cyclic redundancy check (CRC) computing circuit 601 so that error detection can be carried out in a case of reproducing (701); and, in a scrambling circuit 602, scrambling of approximately equalizing the number of ON-pixels and the number of OFF-pixels and adding a pseudorandom-number string in order to prevent repetition of the same pattern is carried out (702).

In a convolutional encoding circuit 603, convolutional encoding which is a type of error correction codes is carried out with respect to the scrambled data (703), the bit sequence of the result of the convolutional encoding is rearranged in an interleaving circuit 604 (704), and modulation is carried out so as to follow RLL rules in a run length limited (RLL) modulating circuit 605 (705).

Herein, RLL modulation will be described. RLL is generally described as RLL (d, k). “d” and “k” represent minimum and maximum run lengths of “0” in a channel data string based on a non-return-to-zero invert (NRZI) rule. For example, RLL (1, ∞) allows “101” in which the run length of “0” is 1, but does not allow a data string such as “11” in which the run length is 0. In this example, a maximum run length is not defined.

Then, the modulation data is two-dimensionally rearranged in a two-dimensional circuit 606 to form two-dimensional data corresponding to one page, a marker serving as a reference in a case of reproducing and a header serving as page information are added thereto (706), and the two-dimensional data is transferred to the spatial light modulator 312 in the pickup 11.

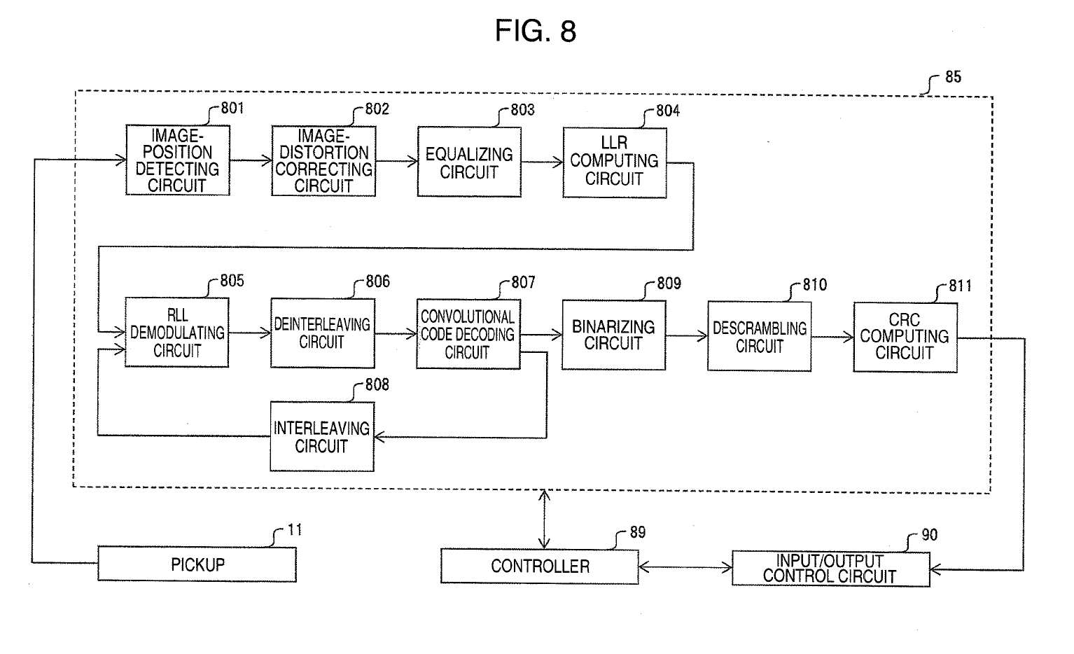

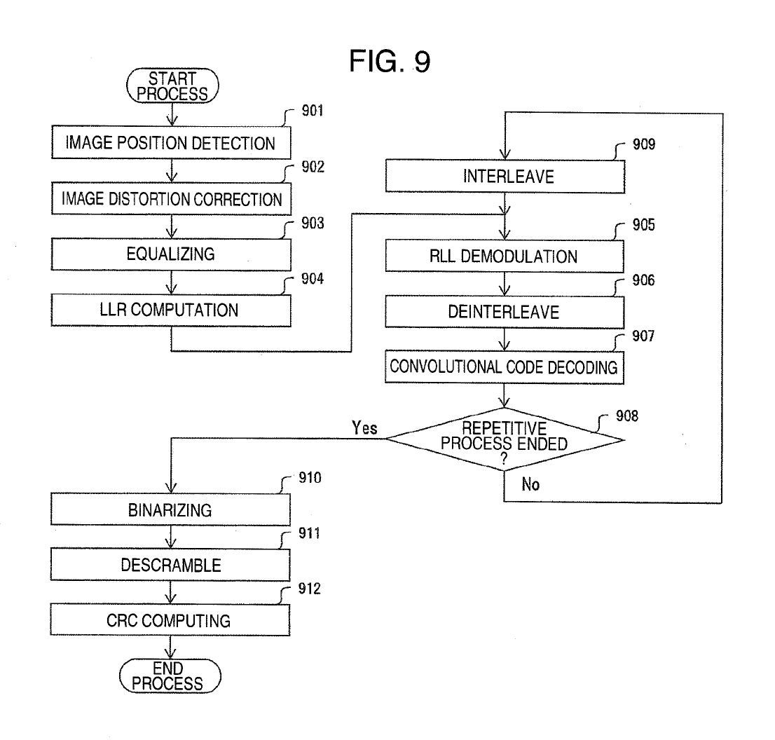

FIG. 8 is a block diagram of the signal processing circuit 85 of the optical-information recording/reproducing device 10, and FIG. 9 is a signal process flow of the signal processing circuit 85.

In a case of reproducing, when the optical detector 225 in the pickup 11 detects image data, the controller 89 orders the signal processing circuit 85 to subject the data corresponding to one page input from the pickup 11 to a reproducing process. An image-position detecting circuit 801 carries out control of detecting a marker from the image data input from the pickup 11 and extracting an effective data range (901). Then, an image-distortion correcting circuit 802 corrects distortions of the inclination, magnification, distortions, etc. of the image by using the detected marker and carries out control of converting the image data to the size of an expected two-dimensional data (902). An equalizing circuit 803 subjects the two-dimensional data to equalization to the characteristics suitable for the process of a log likelihood ration (LLR) computing circuit 804 of a subsequent stage (903).

Herein, the equalizing method will be described. The equalization is carried out by a two-dimensional finite impulse response (FIR) filter, and the filter coefficient thereof can be calculated by using an adaptation algorithm such as a linear minimum mean squared error method (LMMSE). LMMSE is an algorithm of calculating the filter coefficient with which a mean value of square errors of equalized signals and ideal signals becomes minimum as described in Non-Patent Literature 1, “Japanese Journal of Applied Physics Vol. 45, No. 2B, 2006, PP. 1079-1083”. Note that the description has been given by taking LMMSE as an example, but is not limited thereto, and another configuration or algorithm such as a non-linear filter like a Volterra filter may be applied.

Then, since a decoding method of log space is generally used in a later-described RLL demodulating circuit 805, a log likelihood ratio (LLR) is computed in the LLR computing circuit 804 (904).

Herein, an LLR computing method will be described. The LLR is a logarithmic representation of the ratio of the probability that a recorded bit of an output y of the equalizing circuit 803 is 0 and the probability that it is 1 and can be expressed by (FORMULA 1). Note that L(y) means the LLR to be obtained, P(b=0|y) means the probability that b is 0 in y, and P(b=1|y) means the probability that b is 1 in y.

$$\begin{matrix}[ MATH . 1 ] & \\ L ( y ) = log \frac{P ( b = 0 \vert y )}{P ( b = 1 \vert y )} & [ FORMULA 1 ]\end{matrix}$$

However, since P(b=0|y) and P(b=1|y) cannot be directly obtained in a case of decoding, those larger than the mean value of the output y of the equalizing circuit 803 is assumed to be 1, the others are assumed to be 0, and the LLR can be calculated by (FORMULA 2). Note that μ₁ and μ₀ are mean values of 1 and 0, and σ₁ and σ₀ are standard deviations of 1 and 0.

$$\begin{matrix}[ MATH . 2 ] & \\ L ( y ) = log ( \frac{{σ}_{0}}{{σ}_{1}} ) - \frac{1}{2} {( \frac{y - {μ}_{0}}{{σ}_{0}} )}^{2} + \frac{1}{2} {( \frac{y - {μ}_{1}}{{σ}_{1}} )}^{2} & [ FORMULA 2 ]\end{matrix}$$

Note that the LLR computing method has been described in above description. However, the method is not limited thereto, and calculations may be carried out by another method.

Then, in the RLL demodulating circuit 805, RLL modulation data is demodulated based on the output of the LLR computing circuit 804 (905).

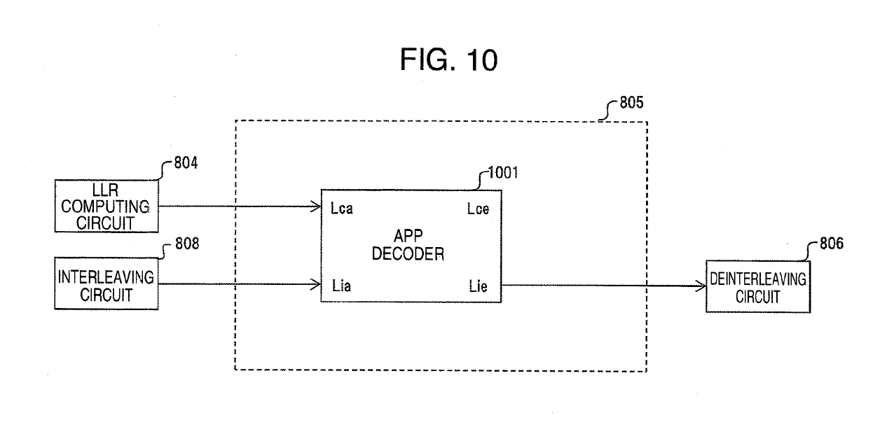

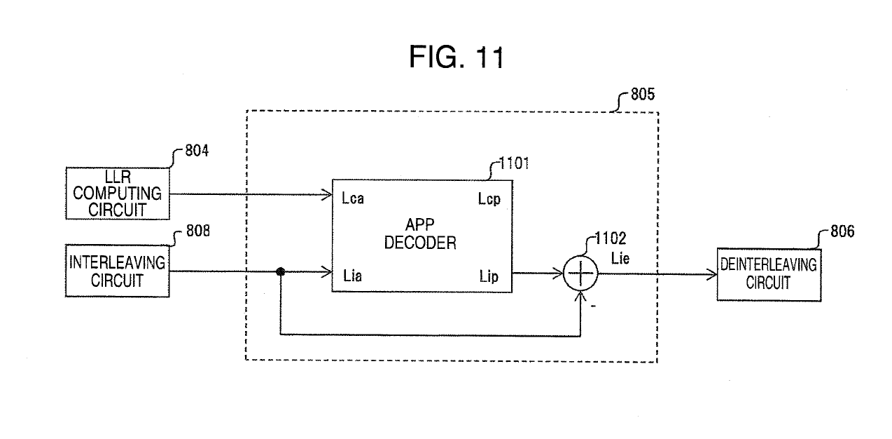

This demodulation will be described by using FIG. 10 and FIG. 11. As shown in FIG. 10, the RLL demodulating circuit 805 is composed of a posterior probability (APP) decoder 1001. The APP decoder 1001 generally receives as input prior information Lca of code data and prior information Lia of information data and outputs external information Lce of code data and external information Lie of information data.

Also, depending on an APP decoder, as shown by an APP decoder 1101 of FIG. 11, there is a case in which posterior information Lcp of code data and posterior information Lip of information data are input; and, in that case, the external information Lce of the code data and the external information Lie of the information data can be obtained by subtracting the prior information from the posterior information by a subtracting circuit 1102. The RLL demodulating circuit 805 inputs the output of the LLR computing circuit 804 serving as Lca and the output of an interleaving circuit 808 serving as Lia to the APP decoder and inputs Lie, which is an output, to a deinterleaving circuit 806. Note that in the first time of later-described repetitive processes, LLR=0 is input since the output of the interleaving circuit 808 is not determined.

Meanwhile, a Bahl, Cocke, Jelinek and Raviv (BCJR) algorithm or the like is preferred to be used in the APP decoder. However, a different algorithm such as soft output viterbi algorithm (SOVA) may be used.

Then, LLR of the output of the RLL demodulating circuit 805 is rearranged so that the rearrangement of the bit sequence by the interleaving circuit 604 is undone by the deinterleaving circuit 806 (906), and convolutional codes are decoded by a convolutional-code decoding circuit 807 based on LLR of the output of the deinterleaving circuit 806 by a BCJR algorithm or the like (907).

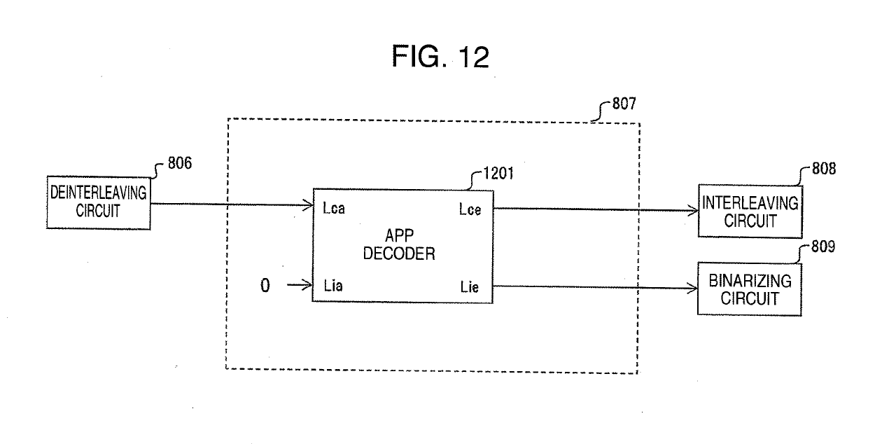

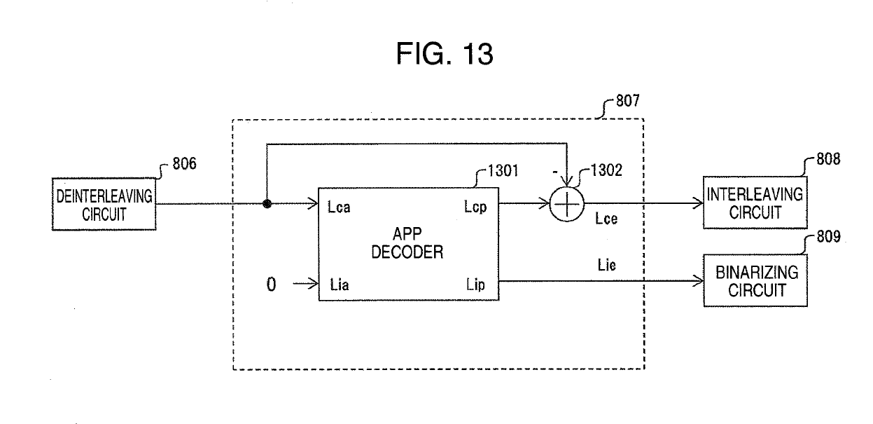

This decoding will be described by using FIG. 12 and FIG. 13. As shown in FIG. 12 and FIG. 13, the convolutional-code decoding circuit 807 is composed of an APP decoder as well as the RLL demodulating circuit 805. The output of the deinterleaving circuit 806 serving as Lca and LLR=0 serving as Lia are input to the APP decoder, Lce which is an output is input to the interleaving circuit 808, and Lie is input to a binarizing circuit 809. Note that if an APP decoder 1301 outputs posterior information as shown in FIG. 13, Lce can be calculated by subtracting Lca from Lcp by a subtracting circuit 1302.

Then, if the repetitive processes are to be executed (908), the output of the convolutional-code decoding circuit 807 is interleaved again by the interleaving circuit 808 and is input to the RLL demodulating circuit 805 as prior information Lia of the information data (909). The performance of decoding can be improved by repeating the processes of the above described RLL demodulating circuit 805, the deinterleaving circuit 806, the convolutional-code decoding circuit 807, and the interleaving circuit 808 multiple times.

If the repetitive processes are to be terminated (908), the binarizing circuit 809 carries out a binarizing process of outputting 1 if LLR of the output of the convolutional-code decoding circuit 807 is 0 or more and outputting 0 if it is less than 0 (910), a descrambling circuit 810 cancels the scrambling of adding pseudorandom-number data strings (911), and, then, a CRC computing circuit 811 checks whether the user data contains an error(s) or not (912). Then, the user data is transferred to the input/output control circuit 90.

The above descriptions are the flows of the signal generating circuit 86 and the signal processing circuit 85. Next, the RLL modulating circuit 605 and the RLL demodulating circuit 805 will be described in detail.

First, a purpose of carrying out RLL modulation in the present Example is to multiply the hologram size in the recording medium by 1/K and enable densification by displaying a pattern, which has undergone RLL modulation in which the minimum run length is K pixels, by the spatial light modulator 312 of the above described pickup 11. Generally, the hologram size recorded in the hologram recording medium can be expressed by (FORMULA 3). “L” represents a hologram size at a Fourier plane (in the hologram recording medium), “f” represents a focal length of an objective lens 315, “λ” represents a wavelength of the optical source 301, and “Δ” represents a pixel size of the spatial light modulator 312.

$$\begin{matrix}[ MATH . 3 ] & \\ L = f \frac{λ}{Δ} & [ FORMULA 3 ]\end{matrix}$$

According to this, it can be understood that the hologram size is inversely proportional to the pixel size of the spatial light modulator 212. Limiting the run length to the K pixels by RLL modulation is equivalent to multiplying the pixel size by K in a pseudo manner. Therefore, if the modulation efficiency of the RLL modulation in which the minimum run length is K pixels can be ensured to be larger than 1/K, the effect of densification is obtained. For this purpose, the maximum run length is not required to be limited.

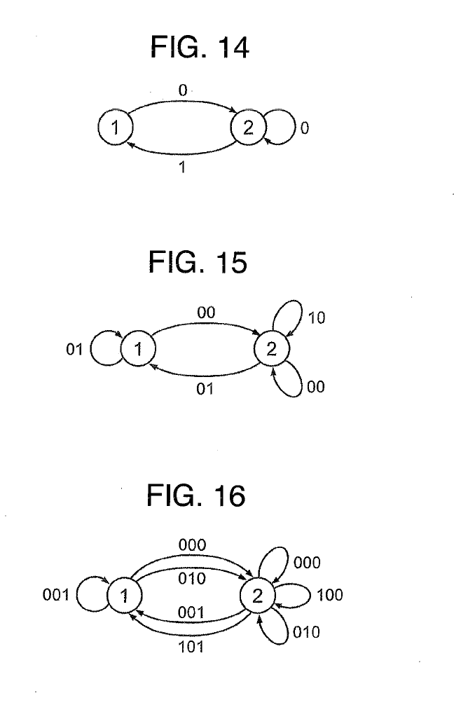

For example, a modulation method of a case in which the minimum run length K=2 pixels in the spatial light modulator 312 will be described by using FIG. 14 to FIG. 22. “The minimum run length K=2 pixels” is a case of d=1 in RLL (d, k) in channel data based on the NRZI rules, and this is used also in RLL (1, 7) of Blu-ray (registered trademark) Disc, which is a conventional optical disk. However, in the conventional optical disk, modulation is carried out by using a table in which input/output bits are defined, and it has been difficult to carry out APP decoding like the RLL demodulating circuit 805.

Therefore, RLL modulation is to be defined by a trellis so as to facilitate APP decoding. First, state transitions of RLL (1, ∞) can be shown by FIG. 14. In FIG. 14, there is no transition in which 1 continues after 1, and it can be understood that the restriction of d=1 is followed. A theoretical limitation of the modulation efficiency of this modulation can be obtained by a base 2 logarithm of the maximum eigenvalue of a transition matrix of the state transitions, and a transition matrix D of FIG. 14 can be expressed by (FORMULA 4).

$$\begin{matrix}[ MATH . 4 ] & \\ D = [ \begin{matrix}0 & 1 \\ 1 & 1\end{matrix} ] & [ FORMULA 4 ]\end{matrix}$$

The maximum eigenvalue of the transition matrix D becomes 1.618, and the theoretical limitation of the modulation efficiency of RLL (1, ∞) is obtained to be 0.6942. In order to simplify the configuration of a modulating/demodulating circuit, the number of input/output bits is preferred to be smaller, and modulation of 2 bits to 3 bits can realize modulation efficiency 0.6666, which is close to the theoretical limitation 0.6942. In this case, since this is the modulation with 3-bit output, through the state transitions of 1 bit of FIG. 14 to the state transitions of 2 bits of FIG. 15, the state transitions of 3 bits of FIG. 16 are taken into consideration. Also, since this is the modulation with 2-bit input, modulation can be carried out if 4 ways (=22 ways) of paths which are combinations of 2 bits are output from each of the two states 1 and 2 in the state transitions of FIG. 16. However, there are only 3 ways of paths from the state 1, where 4 ways of paths are not obtained.

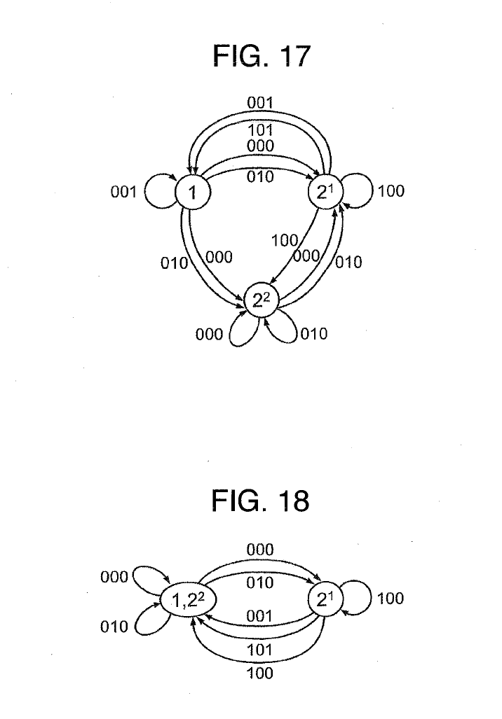

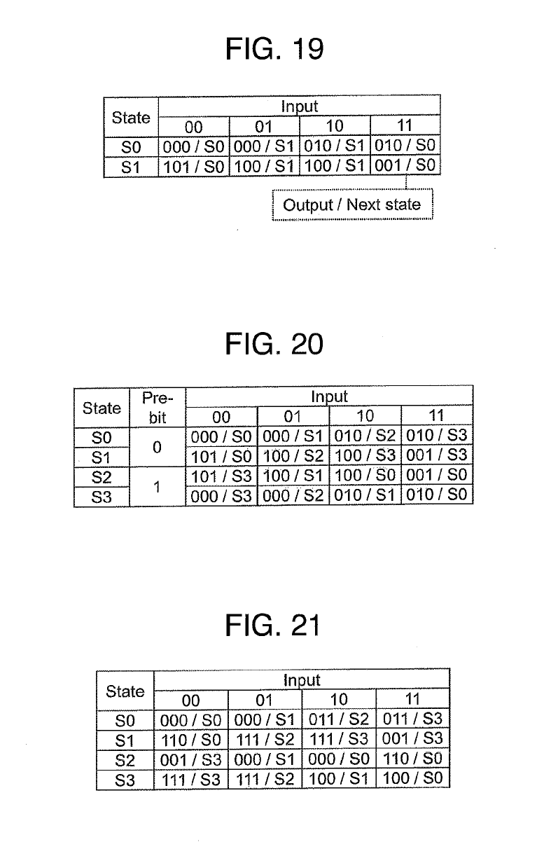

Therefore, first, as shown in FIG. 17, the state 2 is separated into two states, i.e., states 21 and 22. Subsequently, as shown in FIG. 18, the state 1 and the state 22 are caused to degenerate. As a result, four ways of paths from each of the states can be ensured. This is expressed by a table in FIG. 19. In this table, for example, 000/0 of State: S0 and Input: 00 means that, when 00 is input in a state S0, 000 is output, and a transition to a state S0 is made. Incidentally, the previous discussion is the transitions of the channel data based on the NRZI rules, and the data displayed by the spatial light modulator 312 has to be results of dissolving NRZI.

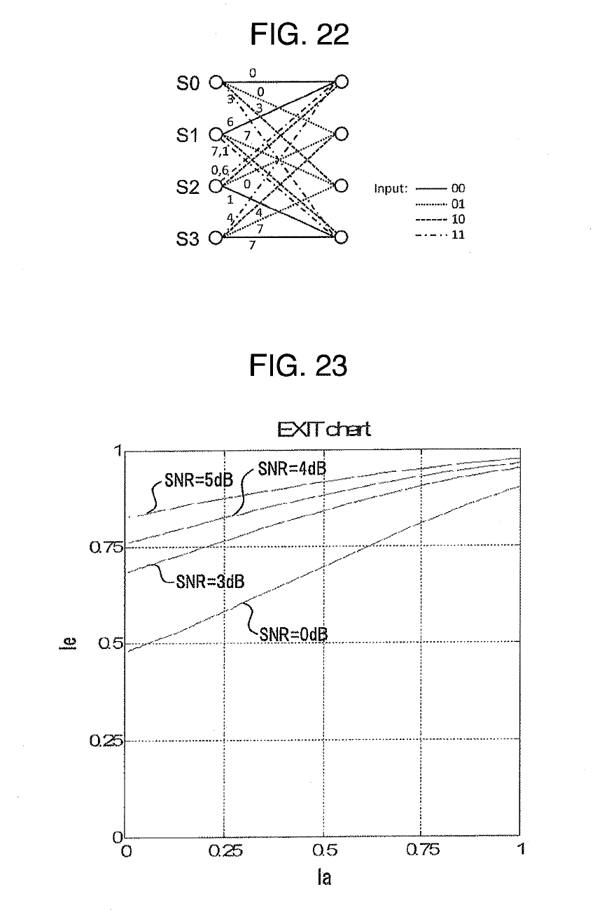

Therefore, as shown in FIG. 20, the transitions of the cases in which the last bit of output in a most-recent transition serves as Prebit are taken into consideration. When NRZI is dissolved with respect to the bit strings thereof, FIG. 21 is obtained. The transitions of FIG. 21 are expressed by a trellis in FIG. 22. In FIG. 22, differences in the line types of paths represent differences of input bits, and the numbers described in the vicinities of the paths represent output bits in an octal notation.

The above example has been described about the case of the minimum run length d=1 of RLL (d, k). However, also the case of d=2 or more and the case in which the maximum run length k is constrained can be described with trellis according to similar ideas.

Herein, extrinsic information transfer (EXIT) analysis results of a case in which demodulation is carried out by the RLL demodulating circuit 805 by using the RLL modulation trellis of FIG. 22 are shown in FIG. 23. EXIT analysis is a method proposed in Non-Patent Literature 2,“S. ten Brink, “Convergence Behavior of Iteratively Decoded Parallel Concatenated Codes” IEEE Transactions on Communications, Vol. 49, No. 10, pp. 1727-1737, October 2001” and is able to visualize changes in the mutual information of input/output. A horizontal axis of FIG. 23 shows mutual information Ia of the data input to Lia of the APP decoder 1001 in FIG. 10, a vertical axis shows mutual information Ie of the data output from Lie, and EXIT curves show differences depending on signal to noise ratio (SNR) of the channel input to Lce. Note that SNR used herein is calculated by using (FORMULA 5). Note that μ₁ and μ₀ are mean values of 1 and 0, and σ₁ and σ₀ are standard deviations of 1 and 0.

$$\begin{matrix}[ MATH . 5 ] & \\ SNR = 20 {log}_{10} \frac{{μ}_{1} - {μ}_{0}}{{σ}_{1} + {σ}_{0}} & [ FORMULA 5 ]\end{matrix}$$

When the EXIT curves of FIG. 23 are checked, in a case of input mutual information Ia=1, output mutual information Ie is not equal to 1, and it can be understood that good performance cannot be obtained in this state.

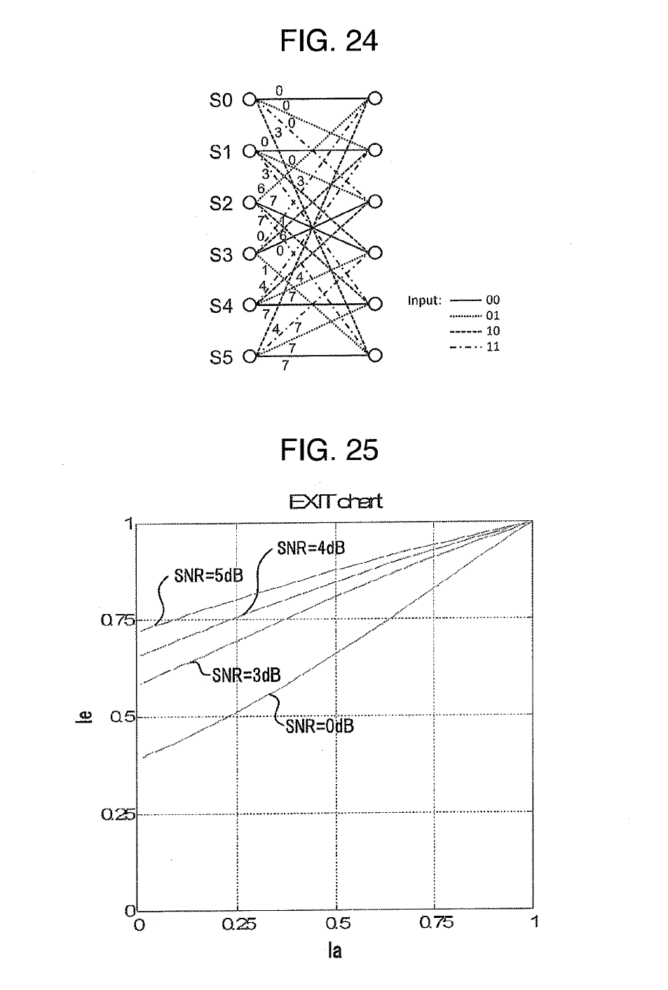

Therefore, the RLL modulation trellis of FIG. 22 is transformed as shown in FIG. 24. While the trellis of FIG. 22 has the parts in which the paths are redundant, the trellis in which S0 and S3 of FIG. 22 are separated and adjusted so that the number of input/output paths of each state becomes 4 is shown in FIG. 24. EXIT analysis results of the RLL demodulating circuit 805 using the RLL modulation trellis of FIG. 24 are shown in FIG. 25. According to the EXIT curves thereof, in a case of input mutual information Ia=1, output mutual information Ie is equal to 1, and a state in which consistency with the later-described EXIT curves of the convolutional-code decoding circuit 807 is easily achieved can be obtained. By the above method, the RLL modulating method can be determined.

Next, the convolutional encoding circuit 603 and the convolutional-code decoding circuit 807 will be described in detail.

First, an important factor for improving performance in the repetitive processes in the RLL demodulating circuit 805, the deinterleaving circuit 806, the convolutional-code decoding circuit 807, and the interleaving circuit 808 is to achieve consistency of the EXIT curves of the RLL demodulating circuit 805 and the convolutional-code decoding circuit 807. As described above, the EXIT curves of the RLL demodulating circuit 805 are shown in FIG. 25, and convolutional codes consistent with that are required.

In order to freely design the code rate of the convolutional code, a punctured code is suitable. The punctured code is a method of obtaining a higher code rate than the convolutional code of an original code by erasing and not outputting some bits of output bits of the convolutional encoder.

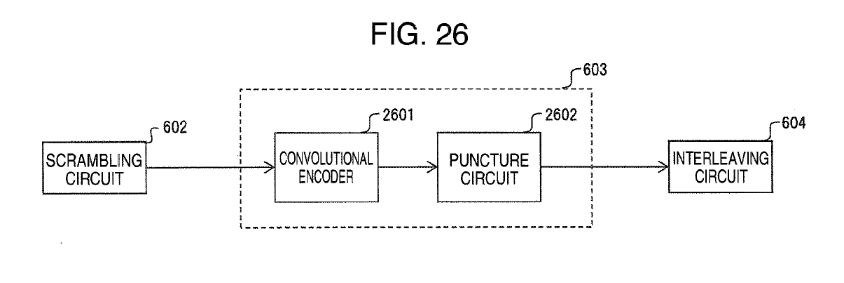

An example of the convolutional encoding circuit 603 to which the punctured code is applied is shown in FIG. 26. The output of the scrambling circuit 602 is subjected to convolutional encoding in a convolutional encoder 2601, is subjected to thin-out of bits in a puncture circuit 2602, and is output. As the convolutional encoder 2601, the configuration of

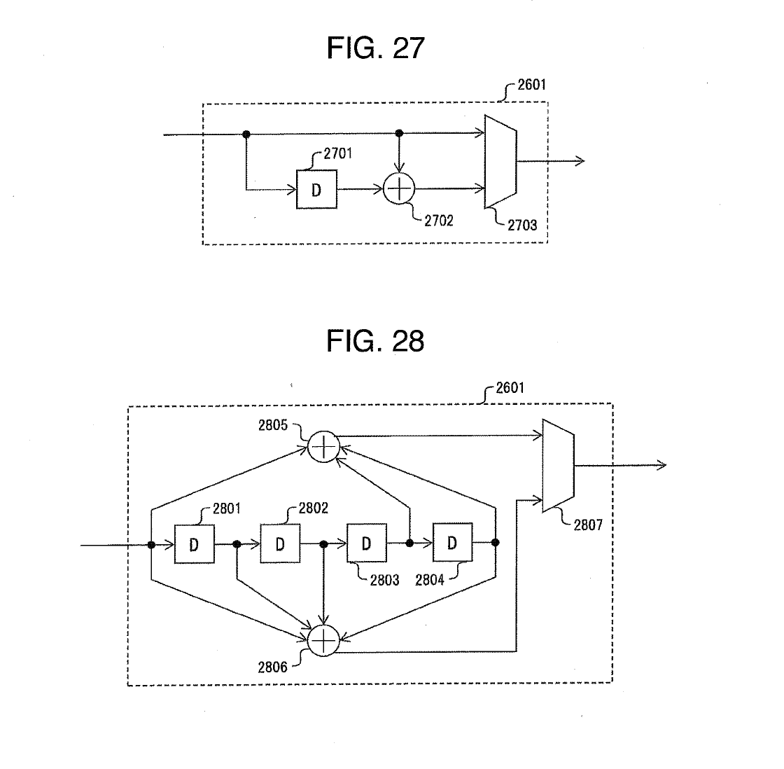

FIG. 27 (constraint length 2) or FIG. 28 (constraint length 5) can be used. This delays the input data by a shift register(s) 2701 or 2801 to 2804, the data is subjected to an exclusive-OR operation(s) in an exclusive-OR circuit(s) 2702 or 2805 and 2806, and bits are sequentially output by a multiplexer 2703 or 2807. Therefore, the convolutional encoder 2601 is configured to output 2 bits with respect to input of 1 bit.

In the puncture circuit 2602, for example, by using a puncture matrix [1101], control is carried out so as not to output 1 bit at the timing of “0” once in 4 bits. According to the above description, the convolutional encoder 2601 has a code rate of 0.5, which is multiplied by 4/3 by puncturing; therefore, the code rate of the convolutional encoding circuit 603 becomes ⅔. Note that, since the punctured code is used, the correction capability can be also controlled by switching the code rate depending on the region of recording and the type of the medium.

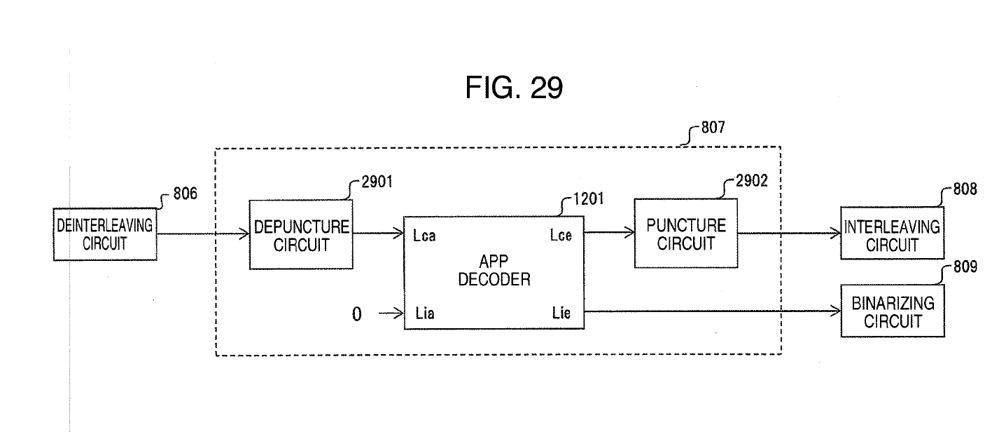

Then, decoding of the punctured code is carried out by inserting data of LLR=0 to the location of the bit(s) thinned out in puncturing and carrying out APP decoding by using the trellis of the original code. Based on this idea, an example of the convolutional-code decoding circuit 807 of the case in which the punctured code is applied is shown in FIG. 29. In a depuncture circuit 2901, the data of LLR=0 is inserted to the output of the deinterleaving circuit 806, it is input to prior information Lca of an APP decoder 1201, and external information Lce is calculated. The external information Lce has to be punctured again since the external information is used as prior information of the information data of the RLL demodulating circuit 805 in the repetitive processes. Therefore, the external information Lce is thinned out in a puncture circuit 2902 and is then input to the interleaving circuit 808.

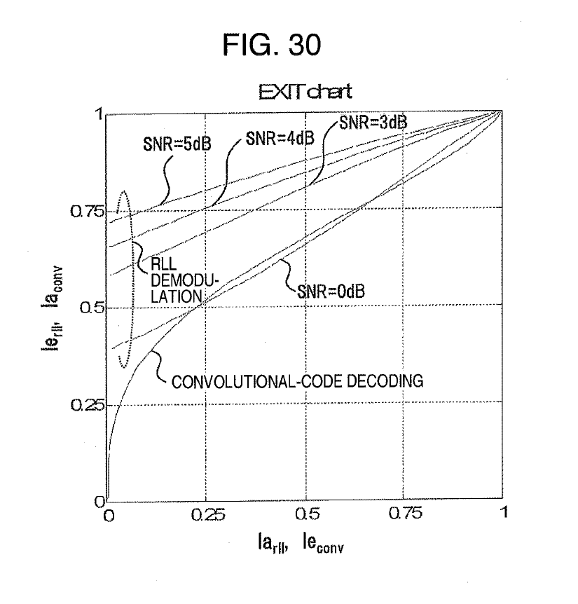

Herein, EXIT analysis results of the convolutional-code decoding circuit 807 using the encoder of FIG. 27 are shown in FIG. 30. The difference from FIG. 23 is that an EXIT curve of convolutional-code decoding is added. Regarding the EXIT curve of the convolutional-code decoding, a horizontal axis represents mutual information Ie of the data output from Lie of the APP decoder 1201 in FIG. 29, and a vertical axis represents mutual information Ia input to Lca.

FIG. 30 shows that decoding can be carried out without errors if mutual information is exchanged between the RLL demodulating circuit 805 and the convolutional-code decoding circuit 807 by the repetitive processes and if the mutual information (horizontal axis) converges to 1. For example, in the case of SNR=0 dB of FIG. 30, the EXIT curves of RLL modulation and the convolutional-code decoding are intermixed before the mutual information reaches 1, and decoding cannot be correctly carried out.

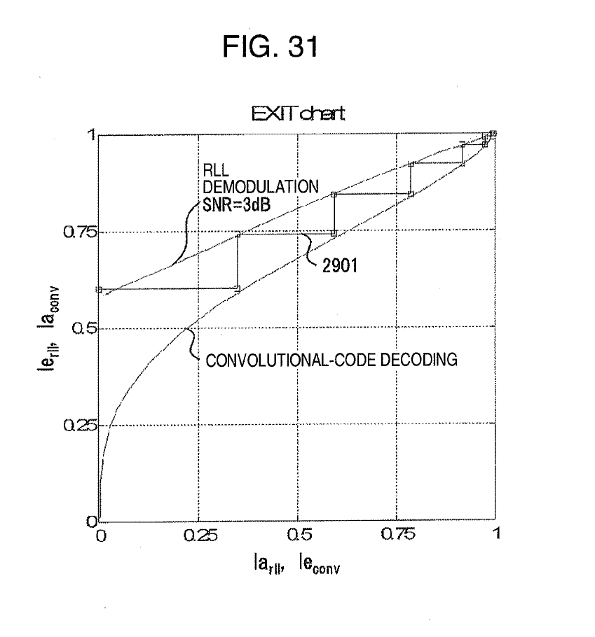

In contrast, in a case of SNR=3 dB, the EXIT curves do not intermix with each other. The exchanges of the mutual information in this case are shown in FIG. 31. The RLL demodulating circuit 805 first outputs mutual information of about 0.6, it is input to the convolutional-code decoding circuit 807, and, as a result of decoding thereof, mutual information of about 0.3 is output.

As a result of the repetition thereof, it can be understood that the mutual information (horizontal axis) output by the convolutional-code decoding circuit 807 is converged to 1. Moreover, the number of repetitions required to converge to 1 can be estimated from this drawing. Therefore, the number of repetitions of the decoding circuit may be determined based on this number of repetitions. Meanwhile, “the mutual information is converged to 1” may be also described as “the mutual information at the intersection point of the two EXIT curves is 1”. Furthermore, the mutual information is not required to be 1, but may be the mutual information with which a bit error rate after decoding becomes a specified value (for example, 10 to the power of −6) and is, for example, 0.9 or more. Furthermore, if an error correction code is added to the data input from the input/output control circuit 90 to the signal generating circuit 86, the mutual information may be a lower value.

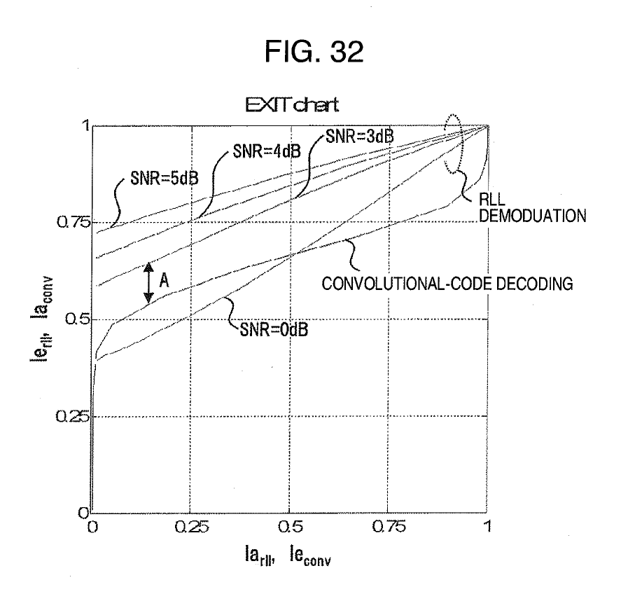

Herein, for reference, the EXIT analysis results of the convolutional-code decoding circuit 807 using the encoder of FIG. 28 are shown in FIG. 32. As a single convolutional-code decoder, the encoder with the constraint length of 5 of FIG. 28 has a higher correction capability than the encoder with the constraint length of 2 of FIG. 27. However, the consistency of the EXIT curves is important as described above in the case of combination with RLL demodulation. If the part at which the curve interval is narrow is present as shown by A of FIG. 32, in a case in which SNR is deteriorated, the curves are intermixed, and, therefore, the correction capability is lowered.

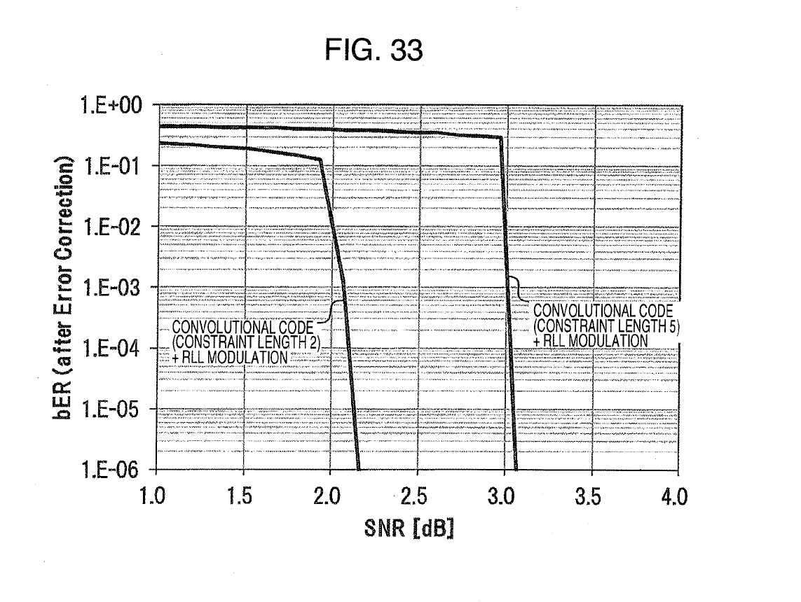

In order to confirm this, the bit error rates as a result of executing the reproducing signal process of FIG. 8 while changing SNR of the reproducing signal are shown in FIG. 33. As a result, it can be understood that the convolutional code with the constraint length 2 which is well consistent with the EXIT curve has a higher correction capability.

According to the above described circuit configurations and processing procedures, reproducing performance can be improved by using the convolutional code suitable for RLL-modulated data.

Note that, the present Example has been described by using the convolutional code as an encoding method combined with RLL modulation, but is not limited thereto and may use a different method such as a repetition code or a single parity code as long as it is a decoding method which can achieve consistency with the EXIT curve of RLL demodulation.

Also, the code rate is 0.66 by using [1101] as the punctured matrix. However, different puncture may be used, for example, the code rate is 0.75 by using [110], or the code rate is 0.70 by using [1101101]. By virtue of this, the correction capability can be freely set.

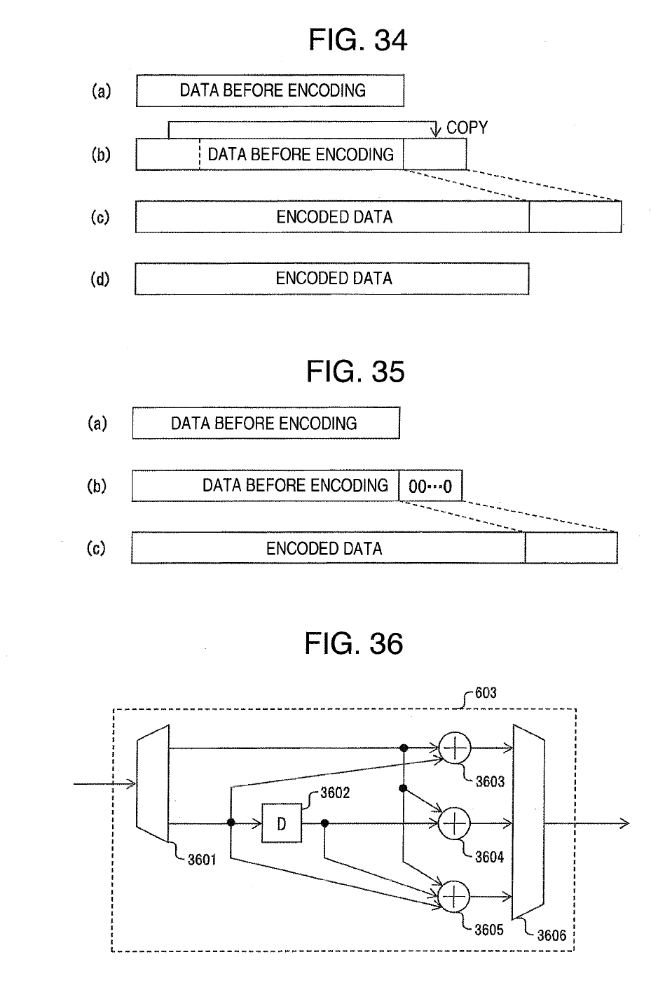

In the convolutional encoding circuit 603, as shown in FIG. 34, (a) to (d), convolutional encoding is carried out in a predetermined processing unit (FIG. 34, (a)), where a termination method according to a tail biting method of: adding first several bits of the processing unit to the end of the processing unit (FIG. 34, (b)), carrying out convolutional encoding (FIG. 34, (c)), and deleting a code word corresponding to the added bits (FIG. 34, (d)) to provide encoded data is effective. By virtue of this, in APP decoding, a decoding path of the terminal can be defined by using decoded data, and the correction capability can be improved.

Other than this, as shown in FIG. 35, (a) to (c), there is also a termination method by a zero-tail method of adding zero to the end of a processing unit. This uses a recording capacity, but the correction capability is high since known data is used. Note that, in either method, the amount of the added data is only required to be about the constraint length of the used convolutional encoder.

The above description can be applied not only to Example 1, but also to other Examples.

### EXAMPLE 2

The present Example is different from Example 1 in the configuration of the convolutional encoding circuit 603. FIG. 36 shows the configuration of the convolutional encoding circuit 603 in the present Example. In Example 1, the punctured code is used in order to realize the convolutional code with the code rate ⅔. However, in the present Example, in order to achieve a code rate ⅔, a convolutional encoder with 2-bit input and 3-bit output shown in FIG. 36 is used. This encoder separates input data into two systems by a demultiplexer 3601, carries out delaying by a shift register 3602, carries out exclusive-OR operations in exclusive-OR circuits 3603 to 3605, and sequentially outputs bits by a multiplexer 3606. This convolutional code has the same characteristics as the Exit curves of the convolutional-code decoding of FIG. 30.

According to the above described configuration, the puncture circuit 2602 of FIG. 26 and the depuncture circuit 2901 of FIG. 29 become unnecessary, and the circuit configuration is simplified.

### EXAMPLE 3

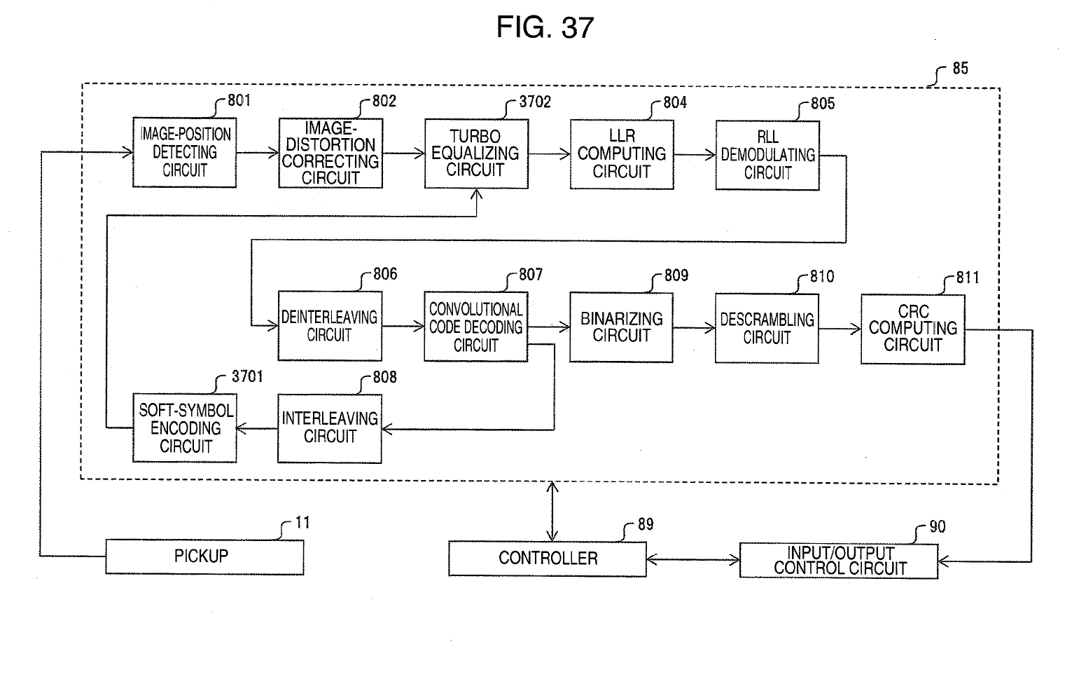

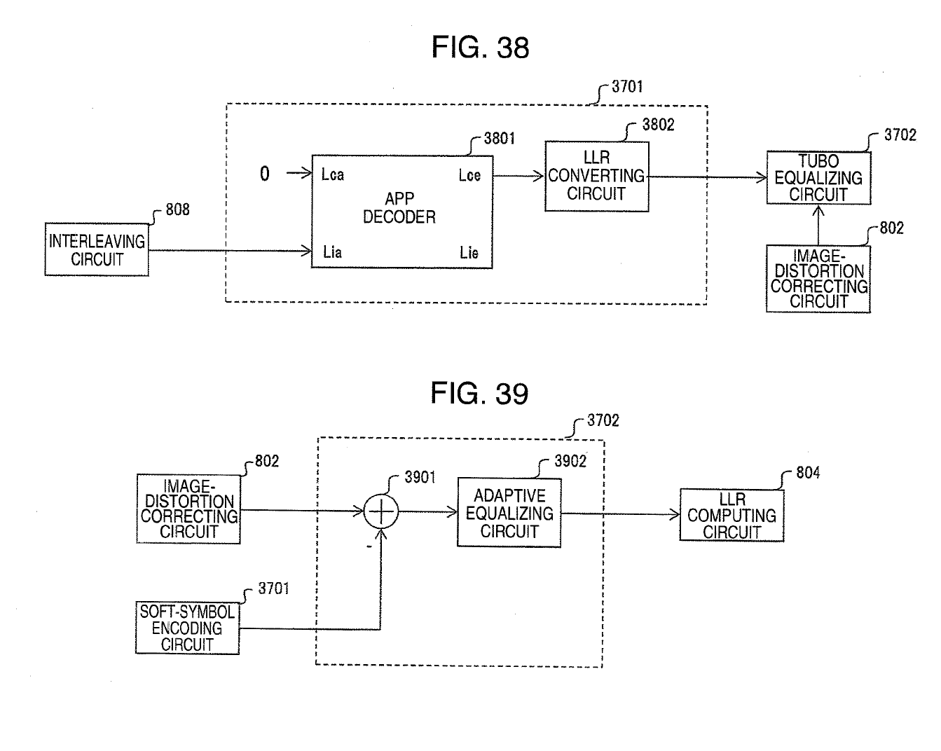

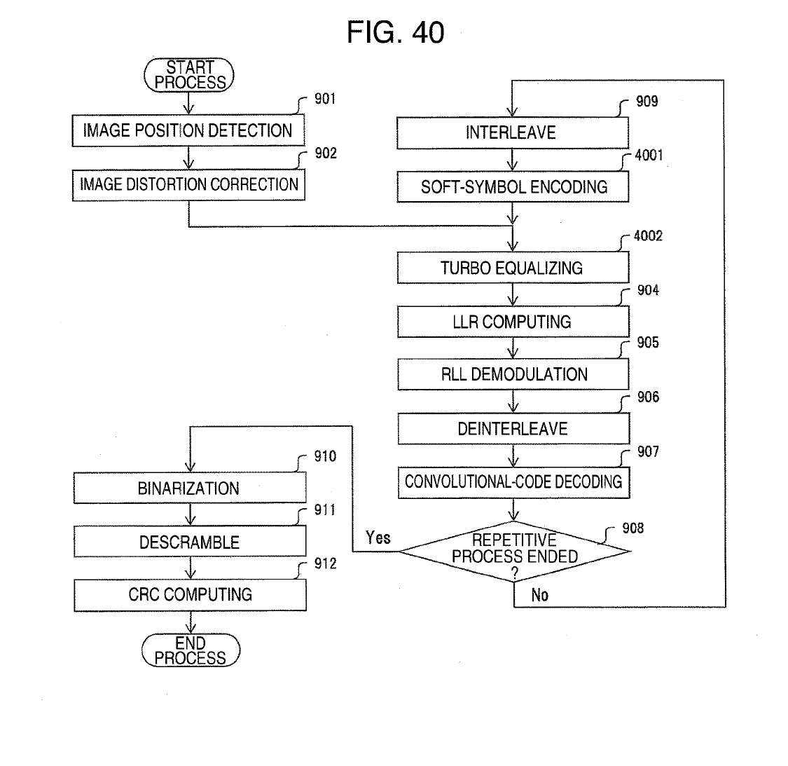

The present Example is different from Example 1 in the configuration of a loop in the repetitive processes in reproducing. FIG. 37 shows the configuration of a signal processing circuit 85 in the present Example. A soft-symbol encoding circuit 3701 and a turbo equalizing circuit 3702 are different from Example 1. The configuration of the soft-symbol encoding circuit 3701 is shown in FIG. 38, and the configuration of the turbo equalizing circuit 3702 are shown in FIG. 39. Also, a signal process flow of the present Example is shown in FIG. 40.

In order to return the output of an interleaving circuit 808 to the equalizing circuit, an expected value of bits in the turbo equalizing circuit 3702 has to be obtained. Therefore, the output of the interleaving circuit 808 is input as prior information Lia of information data to an APP decoder 3801, and external information Lce of code data is obtained. Since this external information is LLR, the expected value of bits is calculated by using (FORMULA 6) in an LLR converting circuit 3802 (4001). This formula can be obtained from the relation of (FORMULA 1) and P(b=0|y)+P(b=1|y)=1.

$$\begin{matrix}[ MATH . 6 ] & \\ \tilde{b} = tanh ( \frac{L ( y )}{2} ) & [ FORMULA 6 ]\end{matrix}$$

Then, in the turbo equalizing circuit 3702, the output of the soft-symbol encoding circuit 3701 is subtracted from the output of an image-distortion correcting circuit 802 by a subtracting circuit 3901, and filter coefficient learning is carried out by using LMMSE or the like by an adaptive equalizing circuit 3902 to carry out equalizing (4002).

Note that, if intersymbol interference is remaining in the signal of the channel and if the interference characteristics thereof are known, the precision of equalizing can be improved by subjecting the interference characteristics to convolution with the output of the soft-symbol encoding circuit 3701.

According to the above described configuration, the loop of the repetitive processes including equalizing can be formed, and the correction capability can be improved.

Note that the present invention is not limited to the above described Examples, but includes various modification examples. For example, above described Examples have been described in detail in order to understandably describe the present invention and are not necessarily limited to be provided with all the described configurations. Moreover, to the configuration of certain Example, the configuration of another Example can be added. Moreover, part of the configurations of Examples can be subjected to addition/deletion/replacement of other configurations. Modification Examples include below configurations.

Modification Example 1 resides in an information reproducing device for reproducing a recording medium recording information, the recording medium recording the information by an information recording device having: an error correction encoding unit subjecting input data to error correction encoding, an interleaving unit rearranging a sequence of output of the error correction encoding unit, and an RLL modulating unit subjecting output of the interleaving unit to RLL modulation based on an RLL modulation trellis; the information reproducing device having: an RLL demodulating unit subjecting a reproducing signal for reproducing the recorded information to RLL demodulation by posterior probability decoding based on the RLL modulation trellis; a deinterleaving unit subjecting output of the RLL demodulating unit to undoing of the rearrangement of the sequence at the interleaving unit; and an error-correction-code decoding unit subjecting output of the deinterleaving unit to error-correction-code decoding by posterior probability decoding based on the error correction encoding.

Modification Example 2 resides in the information reproducing device according to Modification Example 1, characterized in that mutual information at an intersection point of an EXIT curve of the RLL demodulating unit and the error-correction-code decoding unit is approximately 1.

Modification Example 3 resides in the information reproducing device according to Modification Example 1, characterized in that the error correction encoding in the error correction encoding unit uses a convolutional code.

Modification Example 4 resides in the information reproducing device according to claim 3, the information reproducing device characterized in that the convolutional code is a punctured code using a convolutional code having a constraint length of 2 as an original code.

Modification Example 5 resides in the information reproducing device according to Modification Example 1, characterized in that the RLL modulation trellis has 2 as a minimum run length of a bit sequence of the recorded information.

Modification Example 6 resides in the information reproducing device according to Modification Example 5, characterized in that the RLL modulation trellis has 6 as the number of states and has 4 ways as input/output paths of each of the states.

Modification Example 7 resides in the information reproducing device according to claim 1, characterized by having: a soft-symbol encoding unit generating a soft symbol from output of the error-correction-code decoding unit; a subtracting unit subtracting output of the soft-symbol encoding unit from the reproducing signal; and an equalizing unit equalizing output of the subtracting unit.

Modification Example 8 resides in an information reproducing method for reproducing a recording medium recording information, the recording medium recording the information by: an error correction encoding step of subjecting input data to error correction encoding, an interleaving step of rearranging a sequence of output of the error correction encoding step, and an RLL modulating step of subjecting output of the interleaving step to RLL modulation based on an RLL modulation trellis; the information reproducing method having: an RLL demodulating step of subjecting a reproducing signal for reproducing the recorded information to RLL demodulation by posterior probability decoding based on the RLL modulation trellis; a deinterleaving step of subjecting output of the RLL demodulating step to undoing of the rearrangement of the sequence in the interleaving step; and an error-correction-code decoding step of subjecting output of the deinterleaving step to error-correction-code decoding by posterior probability decoding based on the error correction encoding.

Modification Example 9 resides in the information reproducing method according to Modification Example 8, characterized in that mutual information at an intersection point of an EXIT curve of the RLL demodulating unit and the error-correction-code decoding unit is a value close to 1.

Modification Example 10 resides in the information reproducing method according to Modification Example 8, characterized in that the error correction encoding in the error correction encoding unit uses a convolutional code.

Modification Example 11 resides in the information reproducing method according to Modification Example 10, the information reproducing method characterized in that the convolutional code is a punctured code using a convolutional code having a constraint length of 2 as an original code.

Modification Example 12 resides in the information reproducing method according to Modification Example 8, characterized in that the RLL modulation trellis has 2 as a minimum run length of a bit sequence of the recorded information.

Modification Example 13 resides in the information reproducing method according to Modification Example 12, characterized in that the RLL modulation trellis has 6 as the number of states and has 4 ways as input/output paths of each of the states.

Modification Example 14 resides in the information reproducing method according to Modification Example 8, characterized by having: a soft-symbol encoding step of generating a soft symbol from output of the error-correction-code decoding unit; a subtracting step of subtracting output of the soft-symbol encoding step from the reproducing signal; and an equalizing step of equalizing output of the subtracting step.

Modification Example 15 resides in an information recording device for recording information in a recording medium, the information recording device having: an error correction encoding unit subjecting input data to error correction encoding by using a convolutional code; an interleaving unit rearranging a sequence of output of the error correction encoding unit; and an RLL modulating unit subjecting output of the interleaving unit to RLL modulation based on an RLL modulation trellis.

Modification Example 16 resides in the information recording device according to Modification Example 15, characterized in that mutual information at an intersection point of an EXIT curve of posterior probability decoding based on the RLL modulation trellis and posterior probability decoding based on the error correction encoding is approximately 1; or the convolutional code is a punctured code using a convolutional code having a constraint length of 2 as an original code.

Modification Example 17 resides in the information recording device according to Modification Example 15, characterized in that the RLL modulation trellis has 2 as a minimum run length of a bit sequence of the recorded information.

Modification Example 18 resides in the information recording device according to claim 17, characterized in that the RLL modulation trellis has 6 as the number of states and has 4 ways as input/output paths of each of the states.

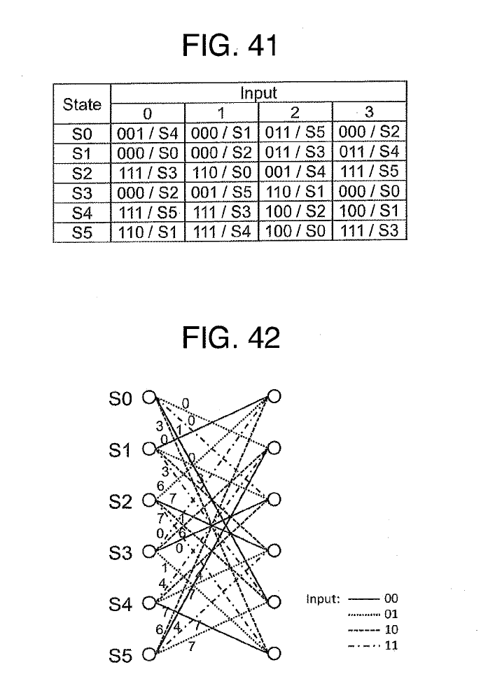

Modification Example 19 resides in the information recording device according to Modification Example 18, characterized in that the RLL modulation trellis is in accordance with state transitions of FIG. 41 or a trellis of FIG. 42.

Modification Example 20 resides in an information recording method for recording information in a recording medium, the information recording method having: an error correction encoding step of subjecting input data to error correction encoding by using a convolutional code; an interleaving step of rearranging a sequence of output of the error correction encoding unit; and an RLL modulating step of subjecting output of the interleaving unit to RLL modulation based on an RLL modulation trellis.

Modification Example 21 resides in the information recording method according to Modification Example 20, characterized in that mutual information at an intersection point of an EXIT curve of posterior probability decoding based on the RLL modulation trellis and posterior probability decoding based on the error correction encoding is approximately 1; or the convolutional code is a punctured code using a convolutional code having a constraint length of 2 as an original code.

Modification Example 22 resides in the information recording method according to claim 20, characterized in that the RLL modulation trellis has 2 as a minimum run length of a bit sequence of the recorded information.

Modification Example 23 resides in the information recording method according to Modification Example 22, characterized in that the RLL modulation trellis has 6 as the number of states and has 4 ways as input/output paths of each of the states.

Modification Example 24 resides in the information recording method according to Modification Example 23, characterized in that the RLL modulation trellis is in accordance with state transitions of FIG. 41 or a trellis of FIG. 42.

The optical-information recording medium is not limited to a recording medium which utilizes holography, but may be, for example, a digital versatile disc (DVD) or a Blu-ray (registered trademark) disc (BD).

Part or all of the above described configurations, functions, processing units, processing means, etc. may be realized by hardware such as designing by integrated circuits. Also, the above described configurations, functions, etc. may be realized by software by interpreting and executing programs, which realize respective functions, by a processor. The information of the programs, tables, files, etc. which realize the functions can be placed in a recording device such as a memory, hard disk, or solid state drive (SSD), or in a recording medium such as an IC card, SD card, or DVD.

The control lines and information lines which are conceivably necessary in terms of description are shown, and all of the control lines and information lines in terms of products are not necessarily shown. It is conceivable in practice that almost all the configurations are mutually connected.

### REFERENCE SIGNS LIST

1 Optical-information recording medium
10 Optical-information recording/ reproducing device
11 Pickup
12 Reproducing reference-beam optical system
13 Disk Cure optical system
14 Disk-rotation-angle detecting optical system
15 Position-detecting optical system
50 Rotary motor
81 Access control circuit
82 Optical-source drive circuit
83 Servo-signal generating circuit
84 Servo control circuit
85 Signal processing circuit
86 Signal generating circuit
87 Shutter control circuit
88 Disk-rotary-motor control circuit
89 Controller
90 Input/output control circuit
91 External control device
201 Optical source
202 Collimator lens
203 Shutter
204 Half-wavelength plate
205 Polarization beam splitter
206 Signal beam
207 Reference beam
208 Beam expander
209 Phase (phase) mask
210 Relay lenses
211 Polarization beam splitter
212 Spatial light modulator
213 Relay lenses
214 Spatial filter
215 Objective lens
216 Polarization-direction converting element
217 Mirror
218 Mirror
219 Mirror
220 Actuator
221 Lens
222 Lens
223 Actuator
224 Mirror
225 Optical detector
401 Optical source
402 Collimator lens
403 Shutter
404 Optical element
405 Polarization beam splitter
406 Signal beam
407 Polarization beam splitter
408 Spatial light modulator
409 Beam expander
410 Relay lens
411 Phase (phase) mask
412 Relay lens
413 Spatial filter
414 Mirror
415 Mirror
416 Mirror
417 Actuator
418 Optical detector
419 Lens
420 Lens
421 Mirror
422 Actuator
423 Reference beam
424 Polarization-direction converting element
425 Objective lens
601 CRC computing circuit
602 Scrambling circuit
603 Convolutional encoding circuit
604 Interleaving circuit
605 RLL modulating circuit
606 Two-dimensional circuit
801 Image-position detecting circuit
802 Image-distortion correcting circuit
803 Equalizing circuit
804 LLR computing circuit
805 RLL demodulating circuit
806 Deinterleaving circuit
807 Convolutional code decoding circuit
808 Interleaving circuit
809 Binarizing circuit
810 Descrambling circuit
811 CRC computing circuit
1001 APP decoder
1101 APP decoder
1102 Subtractor
1201 APP decoder
1301 APP decoder
1302 Subtractor
2601 Convolutional encoder
2602 Puncture circuit
2701 Shift register
2702 Exclusive-or circuit
2703 Multiplexer
2801 to 2804 Shift registers
2805 and 2806 Exclusive-or circuits
2807 Multiplexer
3601 Demultiplexer
3602 Shift register
3603 to 3605 Exclusive-or circuits
3606 Multiplexer
3701 Soft-symbol encoding circuit
3702 Turbo equalizing circuit
3801 APP decoder
3802 LLR converting circuit
3901 Subtractor
3902 Adaptive equalizing circuit

1. An information reproducing device for reproducing a recording medium recording information,
the recording medium recording the information by an information recording device having:
an error correction encoding unit subjecting input data to error correction encoding;
an interleaving unit rearranging a sequence of output of the error correction encoding unit; and
an RLL modulating unit subjecting output of the interleaving unit to RLL modulation based on an RLL modulation trellis,
the information reproducing device comprising:
an RLL demodulating unit subjecting a reproducing signal of the recorded information to RLL demodulation by posterior probability decoding based on the RLL modulation trellis;
a deinterleaving unit subjecting output of the RLL demodulating unit to undoing of the rearrangement of the sequence at the interleaving unit; and
an error-correction-code decoding unit subjecting output of the deinterleaving unit to error-correction-code decoding by posterior probability decoding based on the error correction encoding.

2. The information reproducing device according to claim 1,
wherein mutual information at an intersection point of an EXIT curve of the RLL demodulating unit and the error-correction-code decoding unit is approximately 1.

3. The information reproducing device according to claim 1,
wherein the error correction encoding in the error correction encoding unit uses a convolutional code.

4. The information reproducing device according to claim 1,
wherein the RLL modulation trellis has 2 as a minimum run length of a bit sequence of the recorded information.

5. The information reproducing device according to claim 4,
wherein the RLL modulation trellis has 6 as the number of states and has 4 ways as input/output paths of each of the states.

6. An information reproducing method for reproducing a recording medium recording information,
the recording medium recording the information by:
an error correction encoding step of subjecting input data to error correction encoding;
an interleaving step of rearranging a sequence of output of the error correction encoding step; and
an RLL modulating step of subjecting output of the interleaving step to RLL modulation based on an RLL modulation trellis, the information reproducing method comprising:
an RLL demodulating step of subjecting a reproducing signal of the recorded information to RLL demodulation by posterior probability decoding based on the RLL modulation trellis;
a deinterleaving step of subjecting output of the RLL demodulating step to undoing of the rearrangement of the sequence in the interleaving step; and
an error-correction-code decoding step of subjecting output of the deinterleaving step to error-correction-code decoding by posterior probability decoding based on the error correction encoding.

7. The information reproducing method according to claim 6,
wherein mutual information at an intersection point of an EXIT curve of the RLL demodulating unit and the error-correction-code decoding unit is approximately 1.

8. The information reproducing method according to claim 6,
wherein the error correction encoding in the error correction encoding unit uses a convolutional code.

9. The information reproducing method according to claim 6, wherein the RLL modulation trellis has 2 as a minimum run length of a bit sequence of the recorded information.

10. The information reproducing method according to claim 9,
wherein the RLL modulation trellis has 6 as the number of states and has 4 ways as input/output paths of each of the states.

11. An information recording device for recording information in a recording medium, the information recording device comprising:
an error correction encoding unit subjecting input data to error correction encoding by using a convolutional code;
an interleaving unit rearranging a sequence of output of the error correction encoding unit; and
an RLL modulating unit subjecting output of the interleaving unit to RLL modulation based on an RLL modulation trellis.

12. The information recording device according to claim 11,
wherein mutual information at an intersection point of an EXIT curve of posterior probability decoding based on the RLL modulation trellis and posterior probability decoding based on the error correction encoding is approximately 1.

13. The information recording device according to claim 11,
wherein the RLL modulation trellis has 2 as a minimum run length of a bit sequence of the recorded information.

14. The information recording device according to claim 13,
wherein the RLL modulation trellis has 6 as the number of states and has 4 ways as input/output paths of each of the states.

15. An information recording method for recording information in a recording medium, the information recording method comprising:
an error correction encoding step of subjecting input data to error correction encoding by using a convolutional code;
an interleaving step of rearranging a sequence of output of the error correction encoding unit; and
an RLL modulating step of subjecting output of the interleaving unit to RLL modulation based on an RLL modulation trellis.

16. The information recording method according to claim 15,
wherein mutual information at an intersection point of an EXIT curve of posterior probability decoding based on the RLL modulation trellis and posterior probability decoding based on the error correction encoding is approximately 1.

17. The information recording method according to claim 15,
wherein the RLL modulation trellis has 2 as a minimum run length of a bit sequence of the recorded information.

18. The information recording method according to claim 17,
wherein the RLL modulation trellis has 6 as the number of states and has 4 ways as input/output paths of each of the states.
